(19) United States
(12) Patent Application Publication
(10) Pub. No.: US 2023/0402568 A1
(43) Pub. Date: Dec. 14, 2023

(54) SEMICONDUCTOR DEVICE AND METHOD OF MANUFACTURING THE SAME

(71) Applicant: Hexasolution Co., Ltd., Suwon-si (KR)

(72) Inventors: Duk Kyu BAE, Yongin-Si (KR); Min Ji JO, Gangneung-si (KR)

(21) Appl. No.: 18/085,480

(22) Filed: Dec. 20, 2022

(30) Foreign Application Priority Data
Jun. 9, 2022 (KR) 10-2022-0069964

(51) Int. Cl. H01L 33/16; H01L 33/32; H01L 33/00

(52) U.S. Cl. CPC H01L 33/16; H01L 33/32; H01L 33/007

(57) ABSTRACT

The present disclosure relates to a semiconductor device having a three-dimensional structure capable of increasing a junction area of a semiconductor laminate per unit area of a substrate and a method of manufacturing the same. The semiconductor device includes a substrate having a first orientation plane as a main plane, a partition wall part provided to protrude outward from the main plane, and a semiconductor laminate grown from a side surface of the partition wall part and having, as a growth plane, a second orientation plane having a plane orientation different from that of the first orientation plane.

### CROSS-REFERENCE TO RELATED APPLICATION

This application claims priority to Korean Patent Application No. 10-2022-0069964 filed on Jun. 9, 2022, and all the benefits accruing therefrom under 35 U.S.C. § 119, the contents of which are incorporated by reference in their entirety.

### BACKGROUND

The present disclosure relates to a semiconductor device and a method of manufacturing the semiconductor device, and more particularly, to a semiconductor device having a three-dimensional structure capable of increasing a junction area of a semiconductor laminate per unit area of a substrate and a method of manufacturing the same.

In order for a gallium nitride-based semiconductor device to be used as a white light source in place of an existing mercury lamp or fluorescent lamp, it should not only have excellent thermal stability but also be able to emit high-output light even with low power consumption. To this end, various attempts have been made to improve light extraction efficiency in the gallium nitride-based semiconductor device.

In general, a semiconductor device 10 such as a light emitting semiconductor device or a semiconductor power device has a laminated structure in which an n-type GaN layer 13, a multi quantum wells (MQWs) layer 14 in which a quantum well layer including an InGaN layer and a barrier layer including a GaN layer are alternately laminated, and a p-type GaN layer 15 are sequentially formed by being laminated on a sapphire substrate 11. In the semiconductor device 10 having such a laminated structure, a two-dimensional planar structure in which semiconductor layers 12 to 15 are laminated on an orientation plane (e.g., c-plane) determined according to a crystal orientation of the sapphire substrate 11 (see FIG. 1).

In the semiconductor light emitting device having such a two-dimensional planar structure, there may be a limit to increasing an amount of light emission by increasing light extraction efficiency or light emission efficiency. Meanwhile, if an area of the semiconductor device is increased, a required amount of light emission can be satisfied using a semiconductor light emitting device having the same light emission efficiency, but a single crystal substrate on which a semiconductor device is grown is generally small in area and expensive. In particular, there is a need to reduce the cost for manufacturing an LED using a large-area substrate, but it is not easy to mass-produce a single crystal substrate having large-area, and the manufacturing cost thereof is further increased. Further, in a semiconductor power device, capacitance also increases according to the junction area of a semiconductor layer, but in the semiconductor power device having the two-dimensional planar structure, there may be a limit to an increase in capacitance.

Accordingly, there is a need for a method capable of improving characteristics of the semiconductor device, such as the amount of light emission or capacitance of the semiconductor device, while using a growth substrate having the same area.

Related art includes the following patent literature.

PTL 1: Korean Patent No. 10-1383097

### SUMMARY

The present disclosure provides a semiconductor device capable of increasing a junction area of a semiconductor laminate per unit area of a substrate, and a method of manufacturing the same.

In addition, the present disclosure provides a semiconductor device capable of effectively suppressing residual stress of a semiconductor laminate and a method of manufacturing the same.

In accordance with an exemplary embodiment, a semiconductor device includes a substrate having a first orientation plane as a main plane, a partition wall part provided to protrude outward from the main plane, and a semiconductor laminate grown from a side surface of the partition wall part and having, as a growth plane, a second orientation plane having a plane orientation different from that of the first orientation plane.

The partition wall part may be crystalline, and the side surface of the partition wall part may have the second orientation plane.

The substrate may be a sapphire substrate or a gallium oxide substrate having either an a-plane or an m-plane as the first orientation plane, and the semiconductor laminate may be made of a gallium nitride-based semiconductor layer having a c-plane as the second orientation plane.

A thickness of the partition wall part may be thinner than a thickness of the semiconductor laminate.

A thickness of the partition wall part may be 5 nm to 500 nm.

The partition wall part may be provided in plurality, and a height of the partition wall part may be greater than a separation distance between the plurality of partition wall parts.

An area of an upper end surface of the semiconductor laminate may be smaller than an area of a lower end surface thereof.

The side surface of the partition wall part may be perpendicular to the first orientation plane and parallel to the second orientation plane.

In accordance with another exemplary embodiment, a method of manufacturing a semiconductor device includes a process of preparing a substrate having a first orientation plane as a main plane, a process of forming a partition wall part to protrude outward from the main plane, and a process of depositing a semiconductor laminate on a side surface of the partition wall part to have a second orientation plane having a plane orientation different from that of the first orientation plane as a growth plane.

The process of forming the partition wall part may include a process of forming a preliminary partition wall part made of amorphous material on the substrate, and a crystallization process of changing the preliminary partition wall part to the partition wall part which is crystalline.

The crystallization process may be performed by heat treatment at 1000° C. to 1500° C.

The process of forming the preliminary partition wall part may include a process of forming a pattern-shaped sacrificial layer portion, a process of forming an amorphous material layer on the sacrificial layer portion, and a process of removing the sacrificial layer portion.

During the crystallization process, an upper surface of the partition wall part may be changed to have the first orientation plane, and the side surface of the partition wall part may be changed to have the second orientation plane.

The substrate may be a sapphire substrate or a gallium oxide substrate having either an a-plane or an m-plane as the first orientation plane, and the semiconductor laminate may be made of a gallium nitride-based semiconductor layer having a c-plane as the second orientation plane.

During the process of forming the partition wall part, the partition wall part may be formed such that the side surface of the partition wall part is perpendicular to the first orientation plane and parallel to the second orientation plane.

### BRIEF DESCRIPTION OF THE DRAWINGS

Exemplary embodiments can be understood in more detail from the following description taken in conjunction with the accompanying drawings, in which:

FIG. 1 is a perspective view of a semiconductor device according to the related art;

FIG. 2 is a perspective view of a semiconductor device in accordance with an exemplary embodiment;

FIG. 3 is a perspective view of a semiconductor device in accordance with another exemplary embodiment;

FIG. 4 is a cross-sectional view of the semiconductor device device in accordance with another exemplary embodiment;

FIG. 5 is a flowchart of a method of manufacturing the semiconductor device in accordance with still another exemplary embodiment; and

FIG. 6 is a view for illustrating a process of forming a partition wall part in accordance with still another exemplary embodiment.

### DETAILED DESCRIPTION OF EMBODIMENTS

Hereinafter, embodiments of the present disclosure will be described in more detail with reference to the accompanying drawings. However, the present disclosure is not limited to the embodiments disclosed below and will be implemented in various different forms, and only these embodiments are provided so that this disclosure will be thorough and complete, and will fully convey the scope of the present inventive concept to those skilled in the art. In the description, the same reference numerals are given to the same components, and the drawings may be partially exaggerated in size in order to accurately describe the embodiments of the present disclosure, and the same numerals refer to the same elements in the drawings.

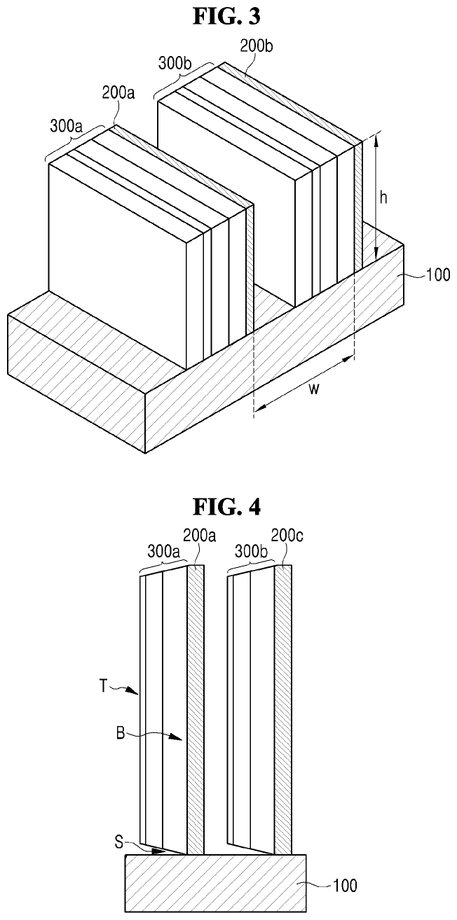

FIG. 2 is a perspective view of a semiconductor device in accordance with an exemplary embodiment, FIG. 3 is a perspective view of a semiconductor device in accordance with another exemplary embodiment, and FIG. 4 is a cross-sectional view of the semiconductor device device in accordance with another exemplary embodiment.

Referring to FIGS. 2 to 4, a semiconductor device according to an embodiment of the present disclosure may include a substrate 100 having a first orientation plane as a main plane, a partition wall part 200 provided to protrude outward from the main plane, and a semiconductor laminate 300 grown from a side surface of the partition wall part 200 and having, as a growth plane, a second orientation plane having a plane orientation different from that of the first orientation plane.

The semiconductor device according to an embodiment of the present disclosure may be a semiconductor light emitting device or a semiconductor power device, but is not particularly limited thereto, and may be various devices using semiconductor characteristics.

The substrate 100 can be selected from oxide single crystal substrates such as sapphire single crystal (Al₂O₃), spinel single crystal (MgAl₂O₄), ZnO single crystal, LiAlO₂ single crystal, LiGaO₂ single crystal, MgO single crystal or Ga₂O₃ single crystal, and non-oxide single crystal substrates such as Si single crystal, SiC single crystal, GaAs single crystal, AlN single crystal, GaN single crystal, or boride single crystal such as ZrB₂. The substrate 100 may be a just substrate or a substrate with an off angle.

The substrate may have an orientation plane in which a main plane providing a growth plane on which a thin film grows is a crystal plane oriented in a specific direction. For example, in the case of the sapphire substrate, the substrate may have a first orientation plane, which is a crystal plane selected from among a-plane, c-plane, m-plane, and r-plane, as the main plane.

Meanwhile, in general, when a single crystal substrate is used, a thin film single crystal grown on the single crystal substrate can be crystal-grown in an orientation based on the orientation plane of the single crystal substrate. For example, a gallium nitride-based semiconductor layer grown on the c-plane of a sapphire single crystal substrate may be formed with the c-plane as a growth plane along the crystal direction of the substrate.

The partition wall part 200 may be provided to protrude outward from the main plane of the substrate 100. That is, the partition wall part 200 may be provided to protrude from the first orientation plane of the substrate 100, and may be in the form of a plate shape, thick film, or membrane shape that has a predetermined thickness and extends two-dimensionally in width and height directions.

The side surface of the partition wall part 200 may be provided so as to protrude perpendicularly to the main plane of the substrate 100, but it does not necessarily have to form a perfect right angle and may be tilted within an orientation tilt tolerance range of certain degree (e.g., ±5°).

The semiconductor laminate 300 may be deposited on the side surface of the partition wall part 200 and may have a second orientation plane having a plane orientation different from that of the first orientation plane of the substrate as the growth plane.

The semiconductor laminate 300 is a laminated structure including a p-type semiconductor layer 310, an active layer 320, and an n-type semiconductor layer 330, and may further include a buffer layer 340 provided between the partition wall part 200 and the n-type semiconductor layer 330, a p-type electrode (not illustrated) electrically connected to the p-type semiconductor layer 310, and an n-type electrode (not illustrated) electrically connected to the n-type semiconductor layer 330.

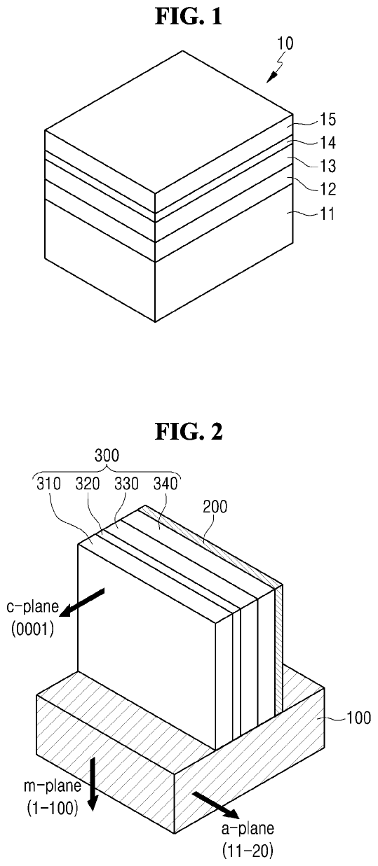

As illustrated in FIG. 1, in the semiconductor device according to the related art, since the semiconductor laminate is formed on the substrate, the semiconductor laminate is crystal-grown with an orientation plane determined according to the orientation plane of the substrate as the growth plane. On the other hand, in the semiconductor device according to the embodiment of the present disclosure, since the semiconductor laminate 300 is deposited on the side surface of the partition wall part rather than the first orientation plane of the substrate, the semiconductor laminate can be grown with the second orientation plane having a plane orientation different from that of the first orientation plane of the substrate as the orientation direction without being oriented and grown along the first orientation plane of the substrate.

The p-type semiconductor layer 310 may be selected from, for example, compound semiconductor materials having a composition formula of InₓAl_{y}Gal_{-x-y}N (0≤x≤1, 0≤y≤1), that is, GaN, AlN, AlGaN, InGaN, InN, InAlGaN, AlInN, etc. and may be doped with a p-type dopant such as Mg, Zn, Ca, Sr, Ba, etc.

The active layer 320 is a region in which electrons and holes are recombined, and as the electrons and holes recombine, the energy level transitions to a lower level, and light having a wavelength corresponding thereto can be generated. The active layer 320 may be formed by including, for example, a compound semiconductor material having a composition formula of InₓAl_{y}Gal_{-x-y}N (0≤x≤1, 0≤y≤1), and may be formed to have a single quantum well structure or a multi quantum well (MQW) structure. The active layer 320 may include a quantum wire structure or a quantum dot structure. A junction area of the semiconductor laminate 300 may be an area of the active layer 320.

The n-type semiconductor layer 330 may be selected from, for example, compound semiconductor materials having a composition formula of InₓAl_{y}Gal_{-x-y}N (0≤x≤1, 0≤y≤1), that is, GaN, AlN, AlGaN, InGaN, InN, InAlGaN, AlInN, etc., and may be doped with a p-type dopant such as Si, Ge, Sn, etc.

In the case of the semiconductor device according to the related art, the semiconductor device has a two-dimensional planar structure, and thus the junction area of the semiconductor layer, such as a light emitting surface, is inevitably smaller than or equal to the area of the substrate. However, in the case of the semiconductor device according to the embodiment of the present disclosure, since the semiconductor laminate 300 is formed on the side surface of the partition wall part 200 protruding from the main plane of the substrate 100 to have a three-dimensional structure, the junction area of the semiconductor layer may be larger than the area of the substrate. That is, the junction area of the semiconductor laminate per unit area of the substrate can be increased due to the three-dimensional structure of the semiconductor device according to the embodiment of the present disclosure, thereby capable of maximizing the amount of light emission or capacitance per unit area of the substrate.

The partition wall part 200 may be crystalline, and the side surface of the partition wall part 200 may have the second orientation plane.

Since the semiconductor laminate 300 grows on the side surface of the partition wall part 200, when the side surface of the partition wall part 200 has an orientation plane having the same crystal orientation as that of the semiconductor laminate 300, respective layers of the semiconductor laminate 300 can grow as components constituting the semiconductor laminate are arranged according to the crystal structure and orientation of the side surface of the partition wall part 200.

The side surface of the partition wall part 200 suffices if it is crystalline having the second orientation plane, and the partition wall part 200 may be made of the same kind of material as the substrate 100 or may be made of a different kind of material. Meanwhile, when the partition wall part 200 is formed along the crystal structure and orientation of the substrate 100, an upper surface of the partition wall part 200 may have the first orientation plane which is an orientation plane of the main plane of the substrate 100.

The substrate 100 may be a substrate having an a-plane or an m-plane as the first orientation plane, and the semiconductor laminate 300 may be composed of a plurality of semiconductor layers having the c-plane as the second orientation plane.

On the other hand, when the substrate 100 is a substrate having the c-plane as the first orientation plane, the side surface of the partition wall part 200 may be the a-plane or m-plane which is the second orientation plane. In this case, the semiconductor laminate 300 may be composed of a plurality of semiconductor layers laminated on the side surface of the partition wall part 200 which is the second orientation plane.

Here, the substrate may be a sapphire substrate or a gallium oxide (Ga₂O₃) substrate, and the plurality of semiconductor layers may be a plurality of gallium nitride-based semiconductor layers.

Sapphire (or gallium oxide) and gallium nitride-based semiconductors have the same hexagonal system crystal structure, and thus the crystal structure of the gallium nitride-based semiconductor layer grown on the orientation plane of sapphire and the resulting optical characteristics by using the orientation plane of sapphire having various orientations can be controlled in various ways. Of course, it is possible to use a gallium nitride substrate instead of a sapphire substrate, but in the case of a gallium nitride single crystal substrate, it is quite expensive and the substrate area is not large, and thus there may be restrictions on its use.

The substrate 100 may be the sapphire substrate or a gallium oxide substrate having either the a-plane or the m-plane as the first orientation plane, and the semiconductor laminate 300 may be composed of the gallium nitride-based semiconductor layer having the c-plane as the second orientation plane.

As illustrated in FIG. 2, the a-plane, m-plane, and c-plane of sapphire (or gallium oxide) or gallium nitride form right angles to each other. When the orientation plane of the main plane of the substrate 100 is the a-plane or the m-plane and the partition wall part 200 formed along the crystal structure and orientation of the substrate 100 is provided so as to protrude vertically from the main plane of the substrate 100, the orientation plane (second orientation plane) of the side surface of the partition wall part 200 may be the c-plane.

Since the semiconductor laminate 300 formed on the side surface of the partition wall part 200 grows along the crystal structure and orientation of the side surface of the partition wall part 200, the semiconductor laminate 300 is grown as the gallium nitride-based semiconductor layer having the c-plane (i.e., the second orientation plane) along the side surface of the partition wall part, which is the c-plane.

The gallium nitride semiconductor layer (having the c-plane) formed on c-plane sapphire (i.e., sapphire having the c-plane) has a faster growth velocity than the gallium nitride semiconductor layer grown on sapphire having another orientation plane (i.e., a-plane, m-plane, or r-plane) and has excellent light emitting characteristics, and thus is generally used in semiconductor devices. As in the present disclosure, when the sapphire substrate having the a-plane or m-plane as the first orientation plane is used and the semiconductor laminate 300 grown on the side surface of the partition wall part 200 is the gallium nitride-based semiconductor layer having the c-plane, a semiconductor device with excellent manufacturing efficiency and optical characteristics may be possible.

Methods for forming the semiconductor laminate 300 include a metal organic vapor deposition (MOCVD) method, a molecular beam epitaxial growth (MBE) method, a hydride vapor deposition (HYPE) method, etc. Preferably, the MOCVD method, which is easy to control the composition and has mass productivity, is suitable, but is not necessarily limited thereto.

When the MOCVD method is used as a method of growing the gallium nitride-based semiconductor layer, trimethylgallium (TMGa) or triethylgallium (TEGa), which is an organometallic material, may be used as a raw material for Ga, and ammonia (NH₃) or hydrazine (N₂H₄) may be used as a raw material for N. Meanwhile, as in the present disclosure, the position (orientation plane) where the gallium nitride-based semiconductor layer is formed can be adjusted by changing a supply ratio, pressure, speed, or process temperature of the raw material gas supplied to the main plane of the substrate 100 and the side surface of the partition wall part 200 having orientation planes with each other. Therefore, if the gallium nitride semiconductor layer is grown under process conditions in which the gallium nitride semiconductor layer having the c-plane (second orientation plane) can grow first, the semiconductor laminate 300 having excellent optical characteristics can be formed on the side surface of the partition wall part 200.

On the other hand, the side surfaces of the partition wall part 200 may include first and second side surfaces facing each other. The first and second side surfaces may be the same orientation plane (i.e., c-plane), and even if the first side surface and the second side surface have the same orientation plane, the side surfaces of the partition wall part 200 may include the first side surface and the second side surface facing each other. The first side surface and the second side surface may be the same orientation plane (i.e., c-plane), and even if the first side surface and the second side surface have the same orientation plane, the first side surface and the second side surface may have polarities different from each other, and thus the gallium nitride semiconductor layer may preferentially grow on any one side surface of the first side surface and the second side surface. Of course, it may be possible to form a semiconductor laminate on both side surfaces of the first side surface and the second side surface.

The thickness of the partition wall part 200 may be thinner than the thickness of the semiconductor laminate 300.

In general, the semiconductor laminate 300 is formed on a bulky substrate 100 thicker than the semiconductor laminate 300 for stable support. When there is a difference in lattice constant between the substrate 100 and the semiconductor layers constituting the semiconductor laminate, a lattice of an epitaxially grown semiconductor layer is stretched or shrunk to match a lattice of the substrate, causing residual stress or crystal defects in the semiconductor layer. In particular, this difference in lattice constant may be more serious when a heterogeneous substrate is used, such as forming the gallium nitride semiconductor layer on the sapphire substrate.

However, in the present disclosure, since the semiconductor laminate 300 is not directly deposited on the substrate 100 having a thick thickness but deposited on the side surface of the partition wall part having a thin thickness, even if there is a difference in lattice constant between the semiconductor laminate 300 and the partition wall part 200, the partition wall part 200 having a thickness thinner than that of the semiconductor laminate 300 may be deformed in the horizontal direction on the base surface, and thus the difference in lattice constant may be mitigated. Accordingly, residual stress or crystal defects of the semiconductor laminate can be effectively reduced.

Furthermore, only one end part (e.g., lower end part) of the partition wall part 200 is fixed to the main plane of the substrate 100 and the other end part (e.g., upper end part) is in an open state, the partition wall part 200 can be freely deformed. Therefore, even if the difference in lattice constant between the semiconductor laminate 300 and the side surface (base surface) of the partition wall part 200 occurs, residual stress or crystal defects of the semiconductor laminate can be effectively suppressed by the freely deformable partition wall part. For example, depending on a relative size of the lattice constant between the semiconductor laminate 300 and the partition wall part 200, the upper end part of the partition wall part 200 in an open state is bent in the thickness direction, so that that the residual stress or crystal defects of the semiconductor laminate can be mitigated. In general, a structural defect in the semiconductor laminate acts as a non-functional recombination site in the semiconductor device, hinders efficient recombination of electrons and holes, and thus may cause a great decrease in light efficiency or capacitance. However, according to the present disclosure, a high-efficiency/high-power semiconductor device may be possible without loss of energy due to the residual stress or crystal defects.

The thickness of the partition wall part 200 may be approximately 5 nm to approximately 500 nm.

Since the side surface of the partition wall part 200 serves as a base surface on which the semiconductor laminate 300 can grow, the partition wall part 200 should not only be able to stand on its own, but also should be able to support the semiconductor laminate 300 to be deposited. In addition, when residual stress or stress caused by the difference lattice constant between the epitaxially grown semiconductor laminate on the side surface of the partition wall part 200 and the side surface of the partition wall part 200 occurs, the partition wall part 200 should be easily deformable in the thickness direction or the horizontal direction to the base surface.

The thickness of the partition wall part 200 is set to approximately 5 nm to approximately 500 nm so that the partition wall part 200 could stand on its own while supporting the semiconductor laminate 300 and be easily deformed according to stress or residual stress of the semiconductor laminate. In order to further improve optical characteristics by suppressing stress or residual stress of the semiconductor laminate, the thickness of the partition wall part 200 may be set to approximately 5 nm to approximately 200 nm so that the partition wall part 200 can be more easily deformed.

If the thickness of the partition wall part is thicker than approximately 500 nm, the partition wall part is not easily deformed and thus stress or residual stress of the semiconductor laminate cannot be mitigated. If the thickness of the partition wall part is thinner than approximately 5 nm, the partition wall part may become unable to stand on its own.

The partition wall part 200 is provided in plurality, and a height h of the partition wall part 200 may be greater than a separation distance w between the plurality of partition wall parts.

In order to effectively increase an area of the light emitting surface per unit area of the substrate by the three-dimensional structure of the semiconductor device according to the embodiment of the present disclosure, the height h of the partition wall part 200 may be greater than the separation distance w between the plurality of partition wall parts. If the height h of the partition wall part 200 is equal to the separation distance w between the plurality of partition wall parts, the effect of the three-dimensional three-dimensional structure of the semiconductor device cannot be expected and the area of the light emitting surface becomes the same as the area of the substrate as in the related art. As the height h of the partition wall part 200 increases, the light emitting surface can be increased, but as described above, the upper limit of the height h can be determined by the physical limit at which the partition wall part having a deformable thickness can stand on its own. For example, the height h of the partition wall part 200 may be greater than the separation distance w between the plurality of partition wall parts and may be approximately 100 μm or less.

An area of an upper end surface T of the semiconductor laminate 300 may be smaller than an area of a lower end surface B thereof. That is, the lower end surface B of the semiconductor laminate 300 in contact with the base surface, which is the side surface of the partition wall part 200, has the same width as that of the side surface of the partition wall part 200, and, as the semiconductor laminate is formed and the thickness thereof increases, the area of the upper end surface is reduced, so that the area of the upper end surface T of the semiconductor laminate 300 may be smaller than the area of the lower end surface B of the semiconductor laminate 300. As a result, the side surface of the semiconductor laminate 300 forms an inclined surface S. It can be understood that this is because nucleation in the semiconductor layer is smoothly performed even at an edge part on the base surface, which is the side surface of the partition wall part, while a nucleation site of the semiconductor layer is not provided at an edge part thereof as the semiconductor laminate 300 grows and thus the area of the semiconductor layer is reduced.

If the area of the upper end surface T of the semiconductor laminate 300 is smaller than the area of the lower end surface B and the side surface thereof forms the inclined surface S, the semiconductor laminate 300 does not come into contact with the main plane of the substrate 100, so that the semiconductor laminate 300 formed on the side surface of the partition wall part 200 is not hindered by the first orientation plane (e.g., a-plane or m-plane) of the substrate 100. In addition, the semiconductor laminate 300 can grow while maintaining an excellent crystalline state along the second orientation plane on the side surface of the partition wall part 200.

The side surface of the partition wall part 200 may be perpendicular to the first orientation plane and parallel to the second orientation plane. That is, a plane in which the side surface of the partition wall part 200 provided perpendicular to the first orientation plane of the main plane of the substrate 100 is parallel to the growth plane of the semiconductor laminate 300 may be included as the second orientation plane. When the semiconductor laminate 300 is formed on the side surface of the partition wall part 200 having this structure, the semiconductor laminate 300 may have the second orientation plane having a plane orientation different from that of the first orientation plane.

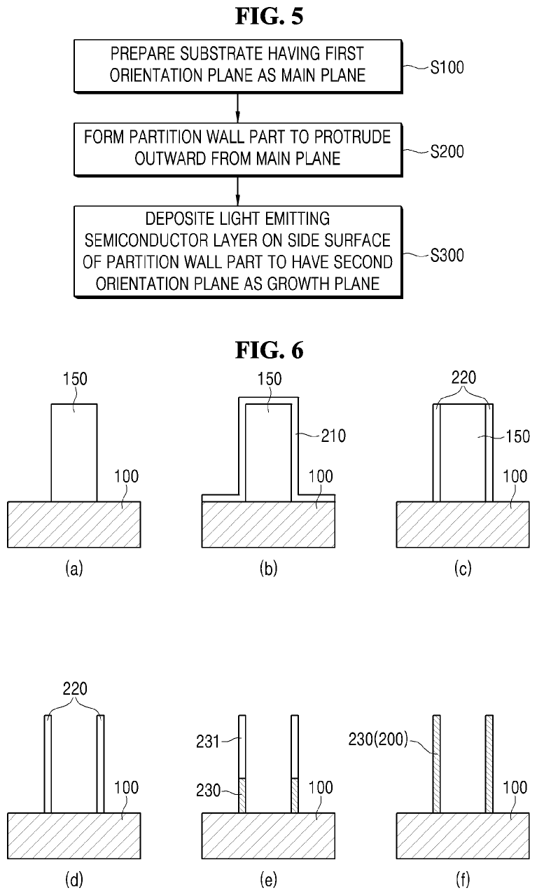

FIG. 5 is a flowchart of a method of manufacturing the semiconductor device in accordance with another exemplary embodiment and FIG. 6 is a view for illustrating a process of forming a partition wall part in accordance with still another exemplary embodiment.

In describing the method of manufacturing the semiconductor device according to another exemplary embodiment of the present disclosure, items overlapping with those described above in relation to the semiconductor device according to another exemplary embodiment will be omitted. Each process of the method of manufacturing the semiconductor device according to another exemplary embodiment does not necessarily have to be performed in a time-series order, and each process may be performed in an opposite order or concurrently, if necessary.

Referring to FIGS. 5 to 6, the method of manufacturing the semiconductor device according to another embodiment of the present disclosure may include a process of preparing a substrate having a first orientation plane as a main plane (S100), a process of forming a partition wall part to protrude outward from the main plane (S200), and a process of depositing a semiconductor laminate on a side surface of the partition wall part to have a second orientation plane having a plane orientation different from the first orientation plane as a growth plane (S300).

First, the substrate having the first orientation plane as the main plane can be prepared (see S100).

The substrate 100 can be selected from oxide single crystal substrates such as sapphire single crystal (Al₂O₃), spinel single crystal (MgAl₂O₄), ZnO single crystal, LiAlO₂ single crystal, LiGaO₂ single crystal, MgO single crystal or Ga₂O₃ single crystal, and non-oxide single crystal substrates such as Si single crystal, SiC single crystal, GaAs single crystal, MN single crystal, GaN single crystal, or boride single crystal such as ZrB₂. The substrate 100 may have a main plane, on which a thin film to be deposited, etc. can be supported, and the main plane of the substrate 100 may have an orientation plane in which a crystal plane is oriented in a specific direction. For example, in the case of a sapphire substrate, it may have a first orientation plane selected from among a-plane, c-plane, m-plane, and r-plane as the main plane.

Next, the partition wall part may be formed to protrude outward from the main plane of the substrate 100 (see S200).

The partition wall part 200 may be provided to protrude from the first orientation plane of the substrate 100, and may be in the form of a plate shape, thick film, or membrane shape that has a predetermined thickness and extends two-dimensionally in width and height directions. The side surface of the partition wall part 200 may be provided so as to protrude perpendicularly to the main plane of the substrate 100, but it does not necessarily have to form a perfect right angle and may be tilted within an orientation tilt tolerance range of certain degree (e.g., ±5°).

Thereafter, a semiconductor laminate may be deposited on the side surface of the partition wall part 200 to have a second orientation plane having a plane orientation different from that of the first orientation plane as a growth plane (see S300).

Unlike depositing the semiconductor laminate on the main plane of the substrate in the related art, the semiconductor laminate 300 having, as a growth plane, the second orientation plane having a plane orientation different from that of the first orientation plane may be deposited on the side surface of the partition wall part 200.

For example, the substrate 100 may be a substrate having the a-plane or the m-plane as the first orientation plane, and the semiconductor laminate 300 may be composed of a plurality of semiconductor layers having the c-plane as the second orientation plane.

On the other hand, when the substrate 100 is a substrate having the c-plane as the first orientation plane, the side surface of the partition wall part 200 may be the a-plane or m-plane which is the second orientation plane. In this case, the semiconductor laminate may be composed of a plurality of semiconductor layers laminated on the side surface of the partition wall part 200 of the second orientation plane.

The semiconductor laminate 300 is a laminated structure including the p-type semiconductor layer 310, the active layer 320, and the n-type semiconductor layer 330, and may further include the buffer layer 340 provided between the partition wall part 200 and the n-type semiconductor layer 330, a p-type electrode (not illustrated) electrically connected to the p-type semiconductor layer 310, and an n-type electrode (not illustrated) electrically connected to the n-type semiconductor layer 330.

Methods for forming the semiconductor laminate 300 include the metal organic vapor deposition (MOCVD) method, the molecular beam epitaxial growth (MBE) method, the hydride vapor deposition (HYPE) method, etc. Preferably, the MOCVD method, which is easy to control the composition and has mass productivity, is suitable, but is not necessarily limited thereto.

When the MOCVD method is used as a method of growing a gallium nitride-based semiconductor layer, trimethylgallium (TMGa) or triethylgallium (TEGa), which is an organometallic material, may be used as a raw material for Ga, and ammonia (NH₃) or hydrazine (N₂H₄) may be used as a raw material for N. Meanwhile, as in the present disclosure, the position (orientation plane) where the gallium nitride-based semiconductor layer is formed can be adjusted by changing a supply ratio, pressure, speed, or process temperature of the raw material gas supplied to the main plane of the substrate 100 and the side surface of the partition wall part 200 having orientation planes with each other. Therefore, if the gallium nitride semiconductor layer is grown under process conditions in which the gallium nitride semiconductor layer having the c-plane (second orientation plane)) can grow first, the semiconductor laminate 300 having excellent optical characteristics can be formed on the side surface of the partition wall part 200.

Meanwhile, the process of forming the partition wall part (S200) may include a process of forming a preliminary partition wall part 200 made of amorphous material on the substrate 100 (S210), and a crystallization process of changing the preliminary partition wall part 220 to the partition wall part 200 which is crystalline (S220).

Since the partition wall part 200 provides a base surface on which the semiconductor laminate 300 is deposited, the partition wall part 200 may be made of crystalline so that the semiconductor laminate 300 can be epitaxially grown. In this case, since it is very difficult to directly form a crystalline partition wall part having a thin thickness on the substrate 100, in the present disclosure, after forming the preliminary partition wall part 220 made of amorphous material, the preliminary partition wall part 220 is crystallized to change into the crystalline partition wall part 200 and 230.

The process of forming the preliminary partition wall part (S210) may include a process of forming a pattern-shaped sacrificial layer portion 150 on the main plane of the substrate 100 (S211), a process of forming an amorphous material layer 210 on the sacrificial layer portion 150 (S212), and a process of removing the sacrificial layer portion 150 (S213).

The pattern-shaped sacrificial layer portion 150 may be formed by depositing an organic material layer made of organic materials such as photoresist and then patterning it. The sacrificial layer portion 150 may extend in one direction so that the partition wall part 200 may have a plate shape, thick film, or membrane shape extending two-dimensionally in width and height directions while having a predetermined thickness.

Next, the amorphous material layer 210 may be formed on the pattern-shaped sacrificial layer 150. In general, in order for a material layer to be deposited in a crystalline state, sufficient energy is required so that the components can form a crystalline structure, whereas in the case of an amorphous material layer, much lower energy may be required than in depositing the crystalline material layer.

Accordingly, the amorphous material layer 210 may be formed on the pattern-shaped sacrificial layer portion 150 made of organic materials at a low temperature. On the other hand, directly forming the crystalline material layer on the pattern-shaped sacrificial layer portion 150 may be very unstable because the sacrificial layer portion is removed by high thermal energy required to deposit the crystalline material layer.

Finally, the preliminary partition wall part 220 may be formed by removing the sacrificial layer portion 150. While the sacrificial layer portion 150 is being removed, the amorphous material layer formed on the upper part of sacrificial layer portion 150 may also be removed. In this case, removal of the sacrificial layer portion may be hindered by the amorphous material layer, and instability of the preliminary partition wall part 220 may be caused as the amorphous material layer formed on the sacrificial layer portion 150 is removed together with the sacrificial layer portion. Accordingly, as another method, the amorphous material layer formed on the upper part of the sacrificial layer portion 150 may be first removed through an anisotropic dry etching method in the state of (b) of FIG. 6 and then the sacrificial layer portion 150 may be removed (see (c) to (d) of FIG. 6).

The crystallization process 5220 may be performed by heat treatment at approximately 1000° C. to approximately 1500° C. Through high-temperature heat treatment, the components constituting the preliminary partition wall part 220 in an amorphous state are converted into a crystalline state while mutually diffusing. Heat treatment may be performed at approximately 1000° C. to approximately 1500° C. to secure a sufficient diffusion velocity and diffusion distance of the components. There may be a problem that, at a temperature lower than approximately 1000° C., energy required for sufficient diffusion cannot be supplied, and at a temperature higher than approximately 1500° C., the stability of the partition wall part having a thin thickness cannot be secured.

During the crystallization process S200, the upper surface of the partition wall part 200 may be changed to have the first orientation plane, and the side surface of the partition wall part may be changed to have the second orientation plane.

When energy is supplied so that the components are sufficiently diffused, the first orientation plane of the main plane of the substrate 100 located under the preliminary partition wall part 220 in an amorphous state serves as a seed layer so that an amorphous region of the preliminary partition wall part 220 is crystallized. Accordingly, the preliminary partition wall part 220 may be crystallized from a lower portion thereof along the crystal structure and orientation of the first orientation plane to change into a crystalline portion 230 (see (e) of FIG. 6). An amorphous portion 231, which is the remaining portion of the preliminary partition wall part, is also crystallized according to the crystal structure and orientation of the crystalline portion 230, and finally, the entire partition wall part 200 is crystallized along the crystal structure and orientation of the first orientation plane to form a crystalline partition wall part (see (f) of FIG. 6).

Since the partition wall part 200 is crystallized along the crystal structure and orientation of the first orientation plane, the upper surface of the partition wall part 200 may have the first orientation plane of the main plane of the substrate 100, and the side surface of the partition wall part 200 may have the second orientation plane having a plane orientation different from that of the first orientation plane. Since the semiconductor laminate 300 is epitaxially grown on the surface side of the partition wall part 200 having the second orientation plane, the semiconductor laminate 300 may be deposited using the second orientation plane as the growth plane.

Meanwhile, the substrate 100 may be a sapphire substrate or a gallium oxide substrate having either the a-plane or the m-plane as the first orientation plane, and the semiconductor laminate may be made of a gallium nitride-based semiconductor layer having the c-plane as the second orientation plane.

In the case where the substrate 100 is a sapphire substrate having the a-plane or m-plane, when the preliminary partition wall part 220 in an amorphous state made of alumina made of alumina (Al₂O₃) is subjected to heat treatment, the alumina in the amorphous state is crystallized along the crystal structure of the sapphire substrate to change into sapphire. Accordingly, the upper surface of the partition wall part may have the same orientation plane as the a-plane or m-plane, which is the main plane of the sapphire substrate, and the side surface of the partition wall part may have the orientation plane of the c-plane perpendicular to the a-plane or the m-plane. Since the gallium nitride semiconductor layer grows on the side surface of the partition wall part having the c-plane, the orientation plane of the gallium nitride semiconductor layer may be the c-plane. Here, although description has been made for the sapphire substrate and alumina, the same may be true for the gallium oxide substrate and gallium oxide having the same crystal structure as the sapphire substrate.

During the process of forming the partition wall part 200 (S200), the partition wall part 200 may be formed such that the side surface of the partition wall part 200 is perpendicular to the first orientation plane and parallel to the second orientation plane. This is achieved, when the pattern-shaped sacrificial layer portion 150 is formed on the main plane of the substrate, by forming the amorphous material layer 210 after forming the pattern-shaped sacrificial layer portion 150 so that the side surface of the pattern-shaped sacrificial layer portion 150 is parallel to the second orientation plane while being perpendicular to the first orientation plane of the main plane.

The meaning of expression ‘on ˜’ used in the above description includes the case of directly contacting and the case of not directly contacting but located opposite to an upper part or lower part, and was used to mean that it is possible not only to be located opposite the entire upper surface or lower surface, but also to be located partially opposite thereto and it faces each other by being separated from each other in position or directly contacts the upper surface or lower surface. In addition, terms such as ‘above’, ‘below’, ‘front end’, ‘rear end’, ‘upper part’, ‘lower part’, ‘upper end’, and ‘lower end’ used in the above description are defined based on the drawings for convenience, and the shape and position of each component are not limited by these terms.

Although the preferred embodiments of the present inventive concept have been shown and described above, the present inventive concept is not limited to the above embodiments. Those skilled in the art to which the present inventive concept pertains without departing from the subject matter of the present inventive concept claimed in the claims will understand that various modifications and equivalent other embodiments are possible therefrom. Therefore, the technical protection scope of the present disclosure should be determined by the claims below.

According to the semiconductor device and the method of manufacturing the semiconductor device according to the embodiment of the present disclosure, the junction area of the semiconductor laminate per unit area of the substrate can be increased due to the three-dimensional structure of the semiconductor device, and thus, the amount of light emission or capacitance per unit area of the substrate can be maximized

Meanwhile, by using the side surface of the partition wall part as a base surface for the growth of the semiconductor laminate, the semiconductor laminate can be grown using, as a growth plane, an orientation plane of a plane orientation different from the orientation plane of the main plane of the substrate, so that crystal characteristics and optoelectronic characteristics of the semiconductor laminate can be effectively controlled.

Since the semiconductor laminate is deposited on the side surface of the partition wall part rather than on a thick substrate, a difference in lattice constant between the semiconductor laminate and the partition wall part can be mitigated because the thin partition wall part can be deformed in the horizontal direction on the growth plane. As a result, residual stress and crystal defects of the semiconductor laminate can be effectively suppressed.

Furthermore, since only one end part (e.g., lower end part) of the partition wall part is fixed to the substrate and the other end part (e.g., upper end part) is in an open state so that the partition wall part can be freely deformed, the residual stress or crystal defects of the semiconductor laminate can be effectively suppressed by the freely deformable partition wall part even when the difference in lattice constant between the semiconductor laminate and the side surface (growth plane) of the partition wall part occurs.

Therefore, according to the semiconductor device and the method of manufacturing the semiconductor device according to the embodiment of the present disclosure, a high-efficiency/high-power semiconductor device can be manufactured without energy loss due to residual stress or crystal defects.

Although the semiconductor device and the method of manufacturing the same have been described with reference to the specific embodiments, they are not limited thereto. Therefore, it will be readily understood by those skilled in the art that various modifications and changes can be made thereto without departing from the spirit and scope of the present inventive concept defined by the appended claims.

What is claimed is:

1. A semiconductor device comprising:
a substrate having a first orientation plane as a main plane;
a partition wall part provided to protrude outward from the main plane; and
a semiconductor laminate grown from a side surface of the partition wall part and having, as a growth plane, a second orientation plane having a plane orientation different from that of the first orientation plane.

2. The semiconductor device of claim 1, wherein
the partition wall part is crystalline, and
the side surface of the partition wall part has the second orientation plane.

3. The semiconductor device of claim 1, wherein
the substrate is a sapphire substrate or a gallium oxide substrate having either an a-plane or an m-plane as the first orientation plane, and
the semiconductor laminate is made of a gallium nitride-based semiconductor layer having a c-plane as the second orientation plane.

4. The semiconductor device of claim 1, wherein a thickness of the partition wall part is thinner than a thickness of the semiconductor laminate.

5. The semiconductor device of claim 1, wherein a thickness of the partition wall part is 5 nm to 500 nm.

6. The semiconductor device of claim 1, wherein
the partition wall part is provided in plurality, and
a height of the partition wall part is greater than a separation distance between the plurality of partition wall parts.

7. The semiconductor device of claim 1, wherein an area of an upper end surface of the semiconductor laminate is smaller than an area of a lower end surface thereof.

8. The semiconductor device of claim 1, wherein the side surface of the partition wall part is perpendicular to the first orientation plane and parallel to the second orientation plane.

9. A method of manufacturing a semiconductor device, comprising:
a process of preparing a substrate having a first orientation plane as a main plane;
a process of forming a partition wall part to protrude outward from the main plane; and
a process of depositing a semiconductor laminate on a side surface of the partition wall part to have a second orientation plane having a plane orientation different from that of the first orientation plane as a growth plane.

10. The method of claim 9, wherein the process of forming the partition wall part comprises:
a process of forming a preliminary partition wall part made of amorphous material on the substrate, and
a crystallization process of changing the preliminary partition wall part to the partition wall part which is crystalline.

11. The method of claim 10, wherein the crystallization process is performed by heat treatment at 1000° C. to 1500° C.

12. The method of claim 10, wherein the process of forming the preliminary partition wall part comprises:
a process of forming a pattern-shaped sacrificial layer portion,
a process of forming an amorphous material layer on the sacrificial layer portion, and
a process of removing the sacrificial layer portion.

13. The method of claim 10, wherein
during the crystallization process,
an upper surface of the partition wall part is changed to have the first orientation plane, and the side surface of the partition wall part is changed to have the second orientation plane.

14. The method of claim 9, wherein
the substrate is a sapphire substrate or a gallium oxide substrate having either an a-plane or an m-plane as the first orientation plane, and
the semiconductor laminate is made of a gallium nitride-based semiconductor layer having a c-plane as the second orientation plane.

15. The method of claim 9, wherein
during the process of forming the partition wall part,
the partition wall part is formed such that the side surface of the partition wall part is perpendicular to the first orientation plane and parallel to the second orientation plane.
